(19) United States
(12) Patent Application Publication
(10) Pub. No.: US 2007/0259215 A1
(43) Pub. Date: Nov. 8, 2007

(54) PERPENDICULAR MAGNETIC RECORDING MEDIA

(75) Inventors: Seidikkurippu Nellainayagam Piramanayagam, Singapore (SG); Jianzhong Shi, Singapore (SG)

Correspondence Address: OCCHIUTI ROHLICEK & TSAO, LLP, 10 FAWCETT STREET, CAMBRIDGE, MA, 02138, US

(73) Assignee: AGENCY FOR SCIENCE, TECHNOLOGY AND RESEARCH, Singapore (SG)

(21) Appl. No.: 11/744,315

(22) Filed: May 4, 2007

(30) Foreign Application Priority Data
May 5, 2006 (SG) 200603052-2

(51) Int. Cl. G11B 5/66; C23C 14/00

(52) U.S. Cl. 428/832; 428/832.3; 204/192.2

(57) ABSTRACT

A method is provided to fabricate a magnetic recording medium which has a magnetic recording layer with reduced grain size. Prior to forming the magnetic recording layer, an intermediate layer is firstly formed, with a boundary phase surrounding and isolating the grains in the intermediate layer. With the formation of the boundary phase, the grain size of the intermediate layer can be successfully reduced. A magnetic recording medium includes an intermediate layer and a magnetic recording layer formed on the intermediate layer. In the intermediate layer, there is formed of segregate grains and a boundary phase which surrounds and isolates the grains, The magnetic layer has magnetic grains formed following the structure of the intermediate layer. The magnetic layer therefore has a relatively smaller grain size than that of conventional medium.

### CROSS-REFERENCE PARAGRAPH

This application claims priority to Singapore Application Number 200603052-2, filed May 5, 2006, the contents of which are hereby incorporated by reference into this application as set forth herein in full.

### TECHNICAL FIELD

The present invention relates to magnetic recording media. In particular, it relates to perpendicular magnetic recording media and a method of fabricating the same.

### BACKGROUND OF INVENTION

Perpendicular magnetic recording media are proposed to provide higher recording density in data storage devices. A typical perpendicular magnetic recording medium includes a substrate and a magnetic recording layer formed over the substrate. One factor that determines the recording density of a perpendicular magnetic recording medium is the size of the magnetic grains in the magnetic recording layer. Reduction of grain size would lead to the possibility to pack more grains in a bit, which may increase the signal-noise ratio at a given density.

Various solutions are proposed in order to reduce the grain size in the magnetic recording layer, and to increase the recording density. In one approach, excessive oxygen is added during the deposition of the magnetic layer, to suppress the growth of the magnetic grains. However, this approach may result in oxygen getting into the magnetic grains. When this happens, the anisotropy constant of the magnetic grains is also reduced, which leads to the formation of superparamagnetic grains. In magnetic recording media, superparamagnetic grains are detrimental to the performance of the magnetic recording, hence are undesirable. The above-mentioned approach is therefore unable to provide a magnetic recording medium with acceptable properties and performances.

It is therefore desirable to provide a perpendicular magnetic recording medium having a reduced grain size in the recording layer, without substantially compromising the recording performance of the magnetic recording media. However, such a solution is presently unavailable.

### SUMMARY OF INVENTION

Embodiments of the present invention provide solutions in the form of reducing the grain size in the magnetic recording layer of a perpendicular magnetic recording medium, and improving the recording performance of the magnetic recording medium.

According to one aspect, there is provided a method of fabricating a magnetic recording medium having a magnetic recording layer with reduced grain size. Prior to forming the magnetic recording layer, an intermediate layer is firstly formed, with a boundary phase surrounding and isolating the grains in the intermediate layer. With the formation of the boundary phase, the grain size of the intermediate layer can be successfully reduced. The boundary phase may be formed of an oxide, a nitride, or an hydride material by, either the addition of oxygen, nitrogen or hydrogen during the formation of the intermediate layer, or providing a target which is formed of a material including an oxide, a nitride, or an hydride, or both. A magnetic recording layer can then be formed on the intermediate layer, and having the grains growing following the grains and boundary phase structure of the intermediate layer hence to obtain a magnetic layer with a smaller grain size. In the meantime, Since the oxygen, nitrogen or hydrogen are in presence prior to the formation of the magnetic layer, the risk of forming superparamagnetic grains in the magnetic recording layer is successfully avoided.

According to another aspect, there is provided a magnetic recording medium having a magnetic recording layer with reduced grain size. The medium has an intermediate layer and a magnetic recording layer formed on the intermediate layer. In the intermediate layer, there is formed of segregate grains, and a boundary phase which surrounds and isolates the grains, The magnetic layer has magnetic grains formed following the structure of the intermediate layer. The magnetic layer therefore has a relatively smaller grain size than that of conventional medium. The boundary phase may be various types of oxide, nitride and/or hydride materials.

### BRIEF DESCRIPTION OF THE DRAWINGS

These and other aspects and advantages of the present invention will be described in detail with reference to the accompanying drawings, in which:

FIG. 1 is a schematic cross sectional view of a magnetic recording medium according to one embodiment of the present invention.

FIG. 2 is a schematic diagram showing formation of intermediate layer in a sputtering chamber according to one embodiment of the present invention;

FIG. 3 is a schematic diagram showing formation of intermediate layer in a sputtering chamber according to another embodiment of the present invention;

FIG. 4 is a TEM image showing grain structure formed in the upper intermediate layer;

FIG. 5 is a schematic diagram showing formation of intermediate layer in a sputtering chamber according to a further embodiment of the present invention;

FIG. 6 is a chart showing a grain size and grain size distribution curve according to one embodiment of the present invention, compared to one of a conventional magnetic recording medium;

FIG. 7 is a TEM image showing a magnetic recording layer formed according to one embodiment of the present invention.

FIG. 8 is a TEM image showing a magnetic recording layer in a conventional magnetic recording medium.

FIG. 9 is a flow chart showing a method of fabricating a magnetic recording medium according to one embodiment of the present invention.

FIG. 10 is a flow chart showing a method of fabricating a magnetic recording medium according to an alternative embodiment of the present invention.

FIG. 11 is a flow chart showing a method of fabricating a magnetic recording medium according to another embodiment of the present invention.

FIG. 12 is a flow chart showing a method of fabricating a magnetic recording medium according to a further embodiment of the present invention.

### DETAILED DESCRIPTION OF THE PREFERRED EMBODIMENTS

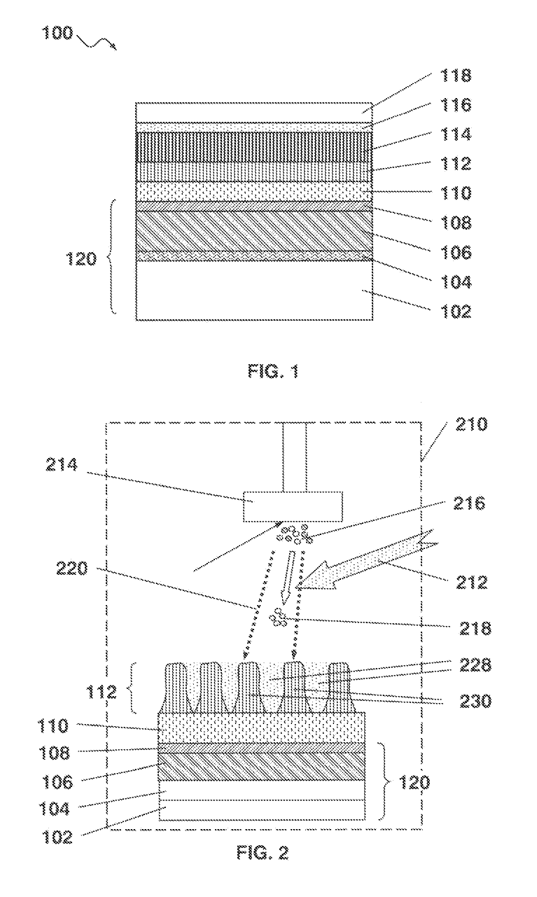

Referring now to FIG. 1, a perpendicular magnetic recording medium 100 according to one embodiment of the present invention includes a base structure 120, lower and upper intermediate layers 110 and 112 disposed on the base structure 120, and a magnetic recording layer 114 disposed on upper intermediate layer 112. Base structure 120 includes a substrate 102, an adhesion layer 104, a soft magnetic layer 106 and a seed layer 108 sequentially formed on a substrate 102.

As shown in FIG. 2, a sputtering chamber 210 is provided for the formation of the intermediate layers and the magnetic recording layer, on top of base structure 120. In the present embodiment, lower intermediate layer 110 is deposited at a pressure of about 0.1 to 1 Pa. By depositing at such a pressure, lower intermediate layer 110 possesses a relatively narrow dispersion of crystallographic orientation of the grains. Thereafter, upper intermediate layer 112 is formed on lower intermediate layer 110, at a pressure higher than the pressure used to deposit lower intermediate layer 110, which is in the range of about 1 to 10 Pa.

To form the upper layer 112, a target 214 is provided in sputtering chamber 210, and to generate materials for forming the upper intermediate layer 112. In the present embodiment, target 214 is made of the materials selected from the group consisting of Ru, Co or an alloy of Ru and Co as the main element. Additional elements such as Cr, Si, Ta, Ti or Al may be added to the target with a concentration not exceeding 50 at %.

During deposition of upper intermediate layer 112, material 216 is generated from target 214. Material 216 therefore includes Ru and/or Co, and Cr and/or either of the materials from the group of Ti, Ta, Al and Si. A gas 212, such as oxygen, nitrogen or hydrogen, is introduced into the sputtering chamber 210. The gas 212 therefore reacts with the materials 216 generated from target 214. In one embodiment, the gas is oxygen which is introduced into the sputtering chamber 210, with a flow rate ratio of about 0.05% to 5%, with respect to the flow rate ratio of the Argon (Ar) gas provided in the sputtering chamber along with oxygen. Such a mixture of Ar and oxygen during the sputtering process would enable oxygen to react with the materials 216, to form oxides of Cr, Ti, Ta, Al or Si 218. The Ru and/or Co elements 220 generated from target 214 deposits onto lower intermediate layer 110, to form Ru and/or Co grains 230. In the meantime, the oxides of Cr or Ti, Ta, Al and Si 218 form a grain boundary phase 228 between the Ru and/or Co grains 230 and isolates the Ru and/or Co grains 230 from each other. Ru and/or Co grains 230 together with grain boundary phase 228 form the upper intermediate layer 112. By formation of grain boundary phase 228 in between and isolating the Ru and/or Co grains 230, the grain size on the upper intermediate layer is successfully reduced.

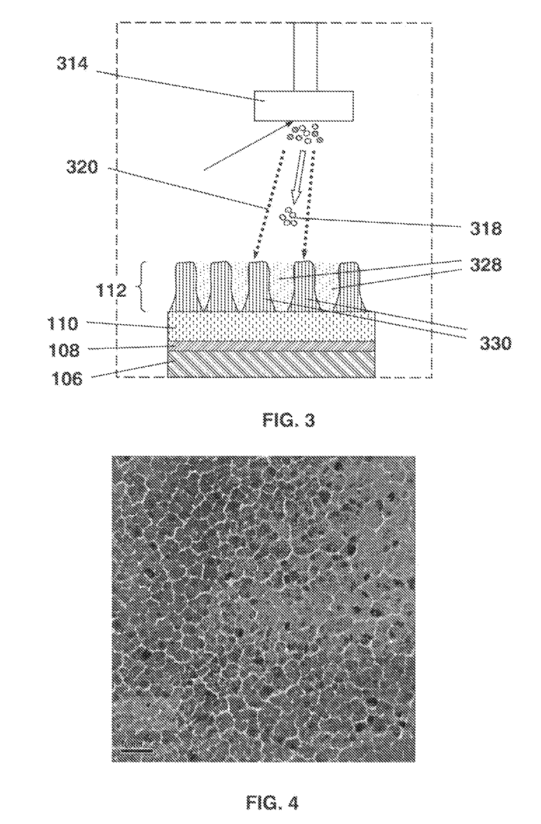

In another embodiment, as shown in FIG. 3, a target 314 that contains oxides or nitrides or Cr or Si, such as Ru:CrO2, Ru:SiO2 or Ru:Cr2O3, is used to deposit the intermediate layer 328. During the sputtering process, target 314 is bombarded to generate Ru material 320 and oxide material 318 which deposit onto lower intermediate layer 110. Ru material 320 then forms Ru grains 330, and oxide material 318 form a grain boundary phase 328 which isolates the Ru grains 330. Ru grains 330 together with grain boundary phase 328 form the upper intermediate layer 112. Grain boundary phase 328 has a similar effect as the grain boundary phase 228 in the previous embodiment, i.e. grain boundary phase 328 isolates Ru grains 330 in the upper intermediate layer 112, and reduces the size of Ru grains 330. In the discussion above, the grain in the intermediate layer itself may have Co as an alternative or an additive element. Optionally, additional oxygen may also be introduced in the sputtering chamber during the sputtering of target 314.

FIG. 4 is a Transmission Electron Microscopy (TEM) image showing the grain structure, with dark zones representing the gains and light areas representing the boundary phase, formed in the upper intermediate layer, with RuCr as the layer-formation material. By controlling the amount and/or pressure of oxygen introduced into the sputtering chamber during the sputtering process, the grain size can be effectively reduced through the formation of the grain boundary phase.

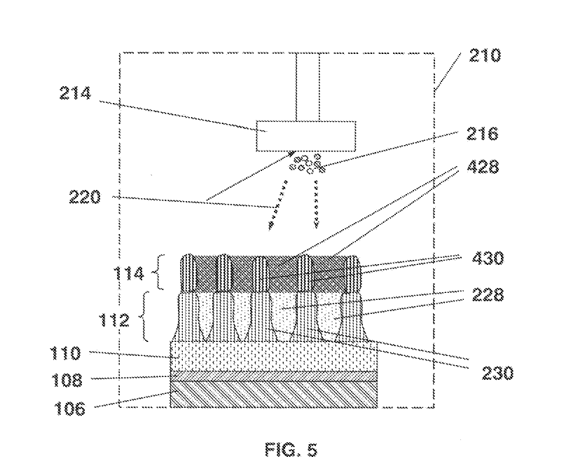

Upon formation of upper intermediate layer 112, under the embodiments shown in FIG. 2 or FIG. 3, subsequent sputtering processes may be carried out in the sputtering chamber, to form magnetic recording layer 114 on top of the upper intermediate layer 112, as shown in FIG. 5.

Through the hetero-epitaxial growth, magnetic grains 430 grow following the structure of Ru grains 230, and magnetic grain boundary phase 428 grow on top of grain boundary phase 228 of the upper intermediate layer 112. From this process, magnetic recording layer having reduced grain size is successfully obtained. It should be appreciated, that since the oxygen, nitrogen or hydrogen is added during the formation of the intermediate layer, the magnetic recording layer is formed with less presence of these substances. As such, generation of superparamagnetic grains in the magnetic recording layer is successfully avoided by the solutions provided according to embodiments of the present invention.

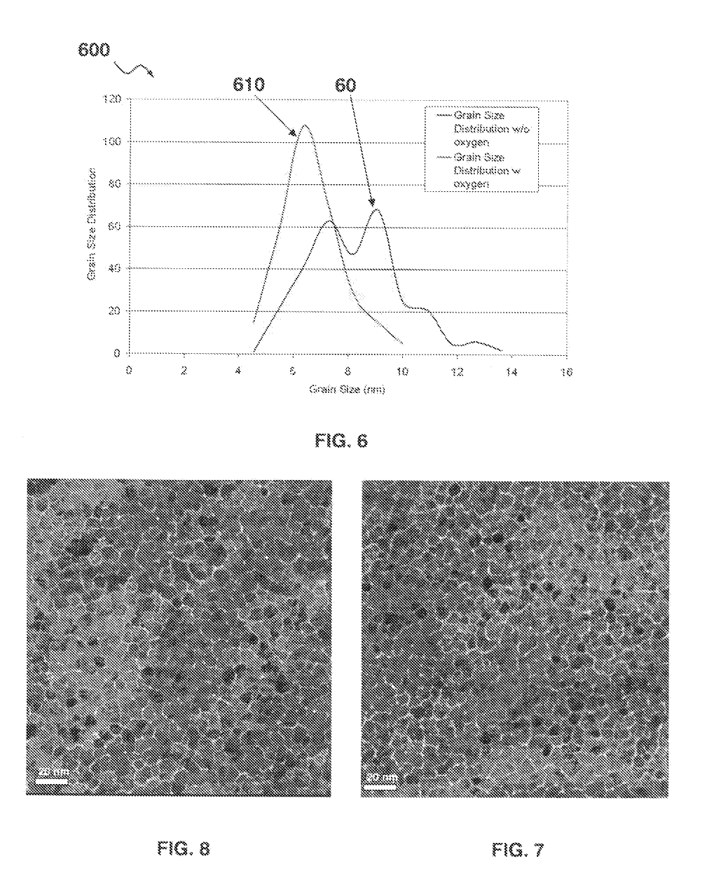

FIG. 6 is a chart 600 showing grain size and grain size distribution curve 610 in a magnetic recording layer formed according to one embodiment of the present invention, compared to a grain size and grain size distribution curve 60 of a conventional magnetic recording medium. It can be seen that firstly, the mean grain size of the magnetic recording layer formed according to embodiment of the present invention is reduced to about 6 nm, which is a significant reduction as compared to those under conventional magnetic recording medium. Secondly, the grain size of the magnetic recording layer formed according to embodiment of the present invention has a narrower distribution, which is about 10% to about 25% of the mean grain size. Both properties contribute to the improvements of the magnetic recording medium performance.

FIG. 7 is a TEM image showing a magnetic recording layer formed according to one embodiment of the present invention. FIG. 8 is a TEM image showing a magnetic recording layer in a conventional magnetic recording medium. In this embodiment, magnetic recording layer is disposed on a RuCr:oxide intermediate layer. Experiment results show that, by using a RuCr:oxide intermediate layer, the grain size in the magnetic recording layer formed according to embodiments of the present invention is reduced to about 6 nm, which is a significant reduction from about 8 nm in conventional magnetic recording media. With magnetic grains reduced to 6 nm, a magnetic recording medium may achieve an areal density of about 400-500 Gb/in².

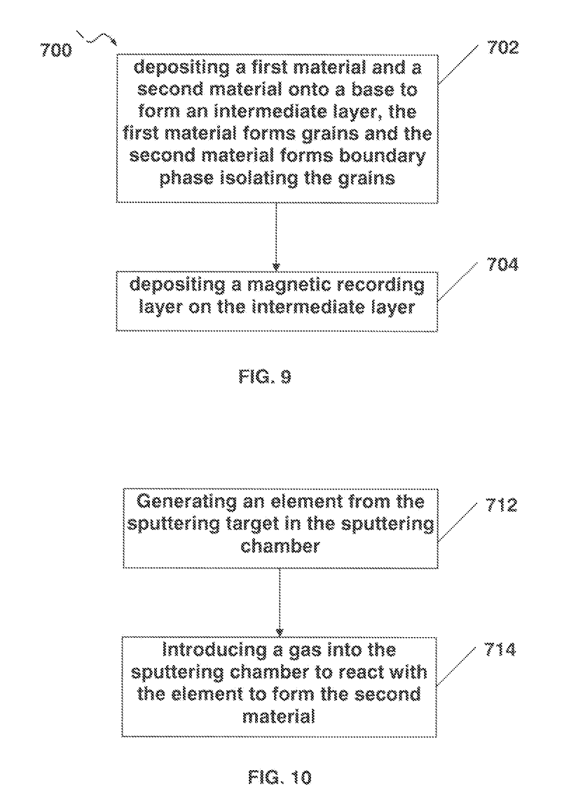

FIG. 9 is a flow chart 700 showing a method of fabricating a magnetic recording medium according to one embodiment of the present invention. At block 702, a first material and a second material are deposited on a base in a sputtering chamber, the first material and second material form an intermediate layer on the base. The first material therefore forms segregate grains in the intermediate layer, and the second material forms a boundary phase between and surrounding the grains. The grain size in the intermediate layer is therefore reduced. Thereafter, shown in block 704, a magnetic recording layer is deposited on top of the intermediate layer. During deposition, magnetic grains grow on top of the grains in the intermediate layer, through hetero-epitaxial growth. As such, the magnetic grain size is effectively reduced following the grains in the intermediate layer.

In one embodiment as shown in FIG. 10, an element, such as Cr or Si, is generated from the target in the sputtering chamber, shown in block 712. A gas, such as an oxygen, a nitrogen or a hydrogen, is introduced into the sputtering chamber, shown in block 714, to react with the element to form the second material.

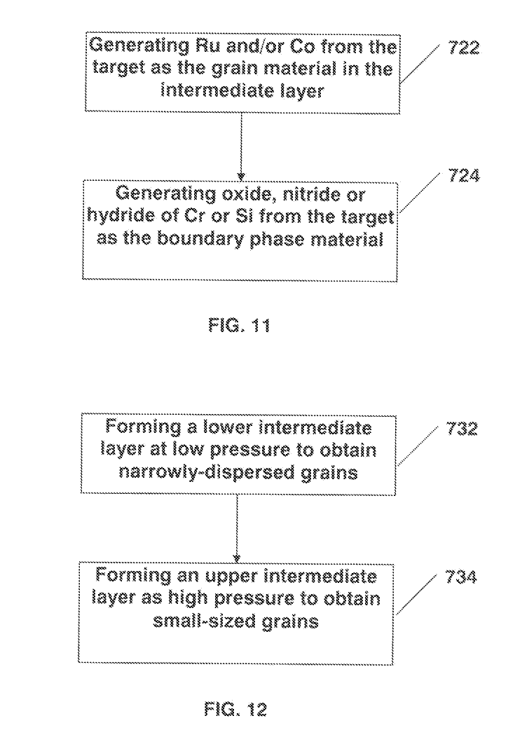

In another embodiment as shown in FIG. 11, the target is made of materials including Ru and/or Co and an oxide, a nitride or a hydride of Cr or Si. During the sputtering process, Ru and/or Co is generated from the target to form the first material (block 722), for the purpose of forming grains in the intermediate layer. The oxide, nitride or hydride of Cr or Si is generated from the target as the second material (block 724). In this embodiment, no introduction of gas or introduction of less gas (as compared to the previous embodiment) into the sputtering chamber is necessary for the purpose of forming oxides, nitrides or hydrides as required in the previous embodiments. The oxide, nitride or hydride generated from the target helps to reduce the flow of reactive gas needed to form the boundary phase in the intermediate layer.

In a further embodiment as shown in FIG. 12, a lower intermediate layer is firstly deposited on the base shown in block 732, and followed by the formation of an upper intermediate layer, shown in block 734. The lower intermediate layer is deposited in a relatively lower pressure of about 0.1 to 1 Pa. Deposited at this pressure, the lower intermediate layer exhibits a narrow dispersion of crystallographic orientation of the grains. The upper intermediate layer is deposited at a relatively higher pressure, for example, of about 1 Pa to 10 Pa or higher. In the present embodiment, depositing at this pressure assists in the formation of the boundary phase in the upper intermediate layer, which isolates the grains in this layer, and reduces the grain size.

Although embodiments of the present invention have been illustrated in conjunction with the accompanying drawings and described in the foregoing detailed description, it should be appreciated that the invention is not limited to the embodiments disclosed, and is capable of numerous rearrangements, modifications, alternatives and substitutions without departing from the spirit of the invention as set forth and recited by the following claims.

1. A method of fabricating a magnetic recording medium, comprising:
depositing a first material and a second material onto a base disposed in a sputtering chamber to form an intermediate layer;
depositing a magnetic recording layer onto the intermediate layer,
wherein the first material forms grains in the intermediate layer, and the second material forms a boundary phase isolating the grains from each other.

2. The method of claim 1, further comprising:
generating an element in the sputtering chamber from a target, wherein the sputtering chamber is filled with a first gas;
introducing a second gas into the sputtering chamber; wherein the additional gas is to react with the element to form the second material.

3. The method of claim 2, wherein the second gas is selected from the group consisting of an oxygen, a nitrogen and a hydrogen.

4. The method of claim 3, wherein the second gas is oxygen and the second material is one or a combination of Cr-oxide, Si-oxide, Ti-oxide, Ta-oxide and Al-oxide.

5. The method of claim 3, wherein the second gas is nitrogen and the second material is one or a combination of Cr-nitride, Si-nitride, Ti-nitride, Ta-nitride and Al-nitride.

6. The method of claim 3, wherein the second gas is hydrogen and the second material is one of a Cr-hydride and a Si-hydride.

7. The method of claim 2, wherein the first material and the element are generated from a target disposed in the sputtering chamber.

8. The method of claim 7, wherein the target is made of a material selected from the group consisting of RuCr, RuSiCr, RuSi, RuCo, CoCr and CoCrRu alloys, wherein the first material is one of Ru, Co and a combination of Ru and Co, and the element is Cr, Ti, Ta, Al or Si.

9. The method of claim 2, wherein the first gas is Argon gas, and wherein the second gas is introduced into the sputtering chamber with a flow rate ratio of about 0.05%-5% with respect to the flow rate of Argon gas.

10. The method of claim 1, wherein the first material and the second material are generated from a target disposed in the sputtering chamber.

11. The method of claim 10, wherein the second material includes at least one of a Cr-oxide, a Si-oxide, Ti-oxide, Ta-oxide, Al-oxide, a Cr-nitride, a Si-nitride, Ti-nitride, Ta-nitride, Al-nitride, a Cr-hydride and a Si-hydride.

12. The method of claim 1, wherein the intermediate layer is an upper intermediate layer, the method further comprising, prior to forming the upper intermediate layer, depositing a lower intermediate layer on the base.

13. The method of claim 12, wherein the lower intermediate layer is deposited at a sputtering chamber gas pressure of about 0.1 Pa to 0.99 Pa and wherein the upper intermediate layer is formed at a pressure of about 1 Pa to 10 Pa.

14. The method of claim 1, wherein the intermediate layer has a mean grain size of about 6 nm and a grain size dispersion of about 10% to 25% of the mean grain size.

15. A magnetic recording medium, comprising:
a substrate;
a plurality of layers formed over the substrate, the plurality of layers including an intermediate layer and a magnetic recording layer formed on the intermediate layer,
wherein the intermediate layer includes segregated grains and a boundary phase isolating the segregate grains from each other.

16. The medium of claim 15, wherein the boundary phase is one selected from the group consisting of an oxide, a nitride and a hydride.

17. The medium of claim 16, wherein the oxide is one or a mixture of a Cr-oxide, Ta-oxide, Ti-oxide, Al-oxide and a Si-oxide.

18. The medium of claim 16, wherein the nitride is one or a mixture of a Cr-nitride, Ta-nitride, Ti-nitride, Al-nitride and a Si-nitride.

19. The medium of claim 16, wherein the hydride is one of a Cr-hydride and a Si-hydride.

20. The medium of claim 15, wherein the intermediate layer has a mean grain size of about 6 nm and a grain size dispersion of about 10% to 25% of the mean grain size.
